(19) United States
(12) Patent Application Publication
(10) Pub. No.: US 2025/0357356 A1
(43) Pub. Date: Nov. 20, 2025

(54) INTERPOSER, SEMICONDUCTOR PACKAGE, AND METHODS FOR MANUFACTURING SAME

(71) Applicant: TOPPAN Holdings Inc., Tokyo (JP)

(72) Inventor: Takashi FUJITA, Tokyo (JP)

(73) Assignee: TOPPAN Holdings Inc., Tokyo (JP)

(21) Appl. No.: 19/285,272

(22) Filed: Jul. 30, 2025

Related U.S. Application Data
(63) Continuation of application No. PCT/JP2024/000177, filed on Jan. 9, 2024.

(30) Foreign Application Priority Data
Feb. 2, 2023 (JP) 2023-014432

(51) Int. Cl. H01L 23/538; H01L 21/48; H01L 23/00; H01L 23/498

(52) U.S. Cl. CPC H01L 23/5386; H01L 21/4857; H01L 23/49894; H01L 23/5383; H01L 24/16; H01L 2224/16227

(57) ABSTRACT

An interposer including: an inner layer structure including an inner layer wiring layer; a first outer layer structure provided on a first surface of the inner layer structure; and a second outer layer structure provided on a second surface of the inner layer structure, the inner layer wiring layer including a first insulating resin layer, a wiring provided on a surface of the first insulating resin layer, and a via being connected to the wiring and penetrating the first insulating resin layer, the first outer layer structure and the second outer layer structure each including a second insulating resin layer and an external connection via penetrating the second insulating resin layer, the second insulating resin layer having an external connection opening part so an external connection electrode of the semiconductor device fits into a surface of one of the first outer layer structure and the second outer layer structure.

### CROSS-REFERENCE TO RELATED APPLICATIONS

The present application is a continuation application of International Application No. PCT/JP2024/000177, filed on Jan. 9, 2024, which is based on and claims priority to Japanese Patent Application No. JP 2023-014432 filed on Feb. 2, 2023, the entire contents of each are incorporated herein by reference.

### TECHNICAL FIELD

The present invention relates to an interposer used for assembling semiconductor devices, a semiconductor package in which semiconductor devices are assembled on an interposer, and methods for manufacturing the same.

### BACKGROUND ART

In recent years, Systems in Package (SiPs) are in practical use in each of which a plurality of semiconductor devices (semiconductor chips) of mutually-different types are installed on an interposer so as to obtain a high-performance semiconductor package. According to this scheme, it is possible, without increasing process costs, to obtain the “semiconductor package” which is a single semiconductor device designed to achieve high performance.

Further, as for the semiconductor devices installed in each of the SiPs described above, there is a tendency that High Bandwidth Memory (HBM), which is a stacked DRAM, is often used. Generally speaking, in HBMs, the pitch of connection terminals is as small as approximately 55 μm. It is therefore necessary to have similar connection terminals formed on the interposers as well.

Further, the abovementioned interposer is to be connected to an FC-BGA. The Coefficient of Thermal Expansion (CTE) of FC-BGAs is approximately 18 ppm/° C., which is higher than the CTE of semiconductor chips being 3 ppm/° C. For this reason, the interposer is required to have a function to mitigate the mismatching of the CTEs between the semiconductor chips and the FC-BGA.

Furthermore, for the sake of convenience in constructing the semiconductor package, it is desirable to be able to assemble the semiconductor devices on the interposer and to subsequently assemble the resulting combination with the FC-BGA. For this reason, it is necessary that the interposer is able to take the form of an independent stand-alone unit separately from the FC-BGA.

To inhibit warping of an interposer, Patent Literature 1 discloses, as a method for manufacturing a semiconductor package (1), a technique including: a step of preparing a laminated body (20) having a plate-like first reinforcement member (5A), a wiring substrate laminated body (2A), and a plate-like second reinforcement member (4A) provided on a second conductor pattern (221); a step of thermally curing an insulating layer by heating the laminated body (20); a step of forming an opening part for exposing a first conductor pattern (224) by selectively removing a part of the first reinforcement member (5A); a step of forming an opening part (41) for exposing the second conductor pattern (221) by selectively removing a part of the second reinforcement member (4A); and a step of connecting a semiconductor power device (3) to the second conductor pattern (221) exposed through the opening part of the second reinforcement member (4A).

### CITATION LIST

### Patent Literature

Patent Literature 1: International Publication No. WO 2013/065287

### SUMMARY OF INVENTION

### Problems to be Solved by the Invention

However, the interposer presented in Patent Literature 1 has a structure in which a fiber base material is impregnated with a resin composition. Thus, as for the diameter of a via that can be formed, 50 μm is the limit for the diameter. In addition, as for the pitch between one via and another via, 130 μm is the limit. Thus, it would be difficult to install HBM, which is a stacked DRAM.

Furthermore, conventional interposers (e.g., fan-out packages, silicon interposers, or the like) and semiconductor packages using a conventional interposer are not expected to go through a step of inspecting the interposer itself and subsequently assembling semiconductor devices thereon.

For this reason, according to conventional manufacturing methods, a plurality of chips are assembled onto an interposer, while the interposer itself has not been inspected and guaranteed.

As a result, yield of semiconductor packages is calculated from a sum of interposer manufacturing defects and chip assembly defects, and it is not possible to separate those factors.

More specifically, manufacturing yield of SiPs may simply be expressed by using Provisional Formula (1) presented below.

The manufacturing yield of SiPs can be expressed as follows:

$$( {Y}_{TOTAL} ) = ( {Y}_{INTERPOSER} ) \times {( {Y}_{ASSEMBLY} )}^{N} \qquad ( 1 )$$

where “interposer yield” (Y_{INTERPOSER}):(Values from 0 to 1);
geometric mean yield of the semiconductor chip assembly “assembly yield” (Y_{ASSEMBLY}): (Values from 0 to 1);
the quantity of the semiconductor devices installed in the SiP:N (an integer of 1 or larger): and
manufacturing yield of SiPs (Y_{TOTAL}):(Values from 0 to 1).

As presented in Formula (1), the manufacturing yield of the SiPs can be calculated as the product of the interposer yield and the chip assembly geometric mean yield raised to the power of the chips.

In this situation, when both the “interposer yield” (Y_{INTERPOSER}) and the “assembly yield” (Y_{ASSEMBLY}) are each 90%, while each SiP has seven chips installed therein, the following are true:

$$( {Y}_{INTERPOSER} ) = ( {Y}_{ASSEMBLY} ) = 90 \% ; and N = 7 \qquad ( 2 )$$

$$( {Y}_{TOTAL} ) = 0.9 \times {0.9}^{7} = 43. \% \qquad ( 3 )$$

Thus, a problem arises where, even if the process yields are each 90%, the manufacturing yield of the SiPs as a whole is extremely low.

For SiPs, a single semiconductor package is structured by assembling a plurality of semiconductor devices. Even if the individual semiconductor devices have been inspected as good products, even a single manufacturing defect of an interposer or a single assembly defect may lead to discarding the entire SiP (all of the plurality of semiconductor devices). As a result, when the quantity of the installed chips increases, a problem arises where the SiP manufacturing yield may exponentially drop, and the quantity of good chips to be discarded may also increase.

Further, conventional manufacturing methods have another problem where, because the entire surfaces of the installed semiconductor devices are hardened with mold resin, it would be impossible, for example, to replace any of the individual semiconductor devices having a manufacturing defect, for repairing purposes.

To make the repairs possible, an electrical inspection before the molding would be required. However, because interposers are thin, handling interposers is difficult, and it is troublesome to carry out the inspection.

To manufacture a thin interposer, a method may be adopted by which various members are stacked on a carrier substrate being rigid, so as to peel off or remove the carrier substrate. According to a manufacturing method using a reversed multilayer scheme by which the stacking on a carrier substrate is started from the semiconductor device installation surface side of an interposer, because a flat surface of the carrier substrate is transferred onto the semiconductor device installation surface, a structure is achieved in which pads on which semiconductor devices are installed and the semiconductor device installation surface have mutually the same flat plane. In contrast, according to a manufacturing method using a forward multilayer scheme by which the stacking on a carrier substrate is started from the side of the surface opposite from the semiconductor device installation surface of an interposer, adopted for the purpose of realizing flatness of the semiconductor device installation surface is a surface polishing step such as polishing called CMP, buff polishing, belt polishing, a grinder method, or a fly cutting method. Thus, a structure is achieved in which pads on which semiconductor devices are installed and the semiconductor device installation surface have mutually the same flat plane.

When assembly is carried out by electrically connecting such flat surfaces to external connection electrodes of the semiconductor devices via the pads, because of a difference in thermal expansion between the interposer and the semiconductor devices or weak holding power of the semiconductor devices in the plane direction of the interposer, a problem may arise where a manufacturing defect occurs due to an assembly position misalignment.

To cope with the above, it is an object of the present invention to provide an interposer that has independence for repairability and further makes it possible to prevent electrical connection failures which may be caused by such an assembly position misalignment of the semiconductor devices.

### Means for Solving the Problems

To solve the problems described above, one of representative interposers of the present invention is provided with: an inner layer structure including at least one inner layer wiring layer; a first outer layer structure provided on a first surface of the inner layer structure; and a second outer layer structure provided on a second surface of the inner layer structure. Further, the inner layer wiring layer includes a first insulating resin layer, a wiring provided on a surface of the first insulating resin layer, and a via being connected to the wiring and penetrating the first insulating resin layer. The first outer layer structure and the second outer layer structure each include a second insulating resin layer and an external connection via penetrating the second insulating resin layer. The second insulating resin layer has an external connection opening part so as to make it possible for an external connection electrode of a semiconductor device to fit into a surface of one of the first outer layer structure and the second outer layer structure.

### Advantageous Effects of Invention

According to the present invention, it is possible to provide an interposer that has independence for repairability and makes it possible to prevent electrical connection failures which may be caused by an assembly position misalignment of a semiconductor device.

Problems, configurations, and advantageous effects other than those described above will become clear from the descriptions of the embodiments for carrying out the invention presented below.

### BRIEF DESCRIPTION OF DRAWINGS

FIG. 1 presents examples of schematic cross-sectional views of an interposer and a semiconductor package according to a first embodiment.

FIG. 2 is a drawing showing an example of the shapes of external connection opening parts of the interposer according to the first embodiment.

FIG. 3 is a chart showing a relationship between CTEs of an entirety and CTEs of outer layer structures.

FIG. 4 is a chart showing a relationship between manufacturing defect ratios and interposer thicknesses.

FIG. 5 presents drawings for explaining manufacturing steps of the interposer according to the first embodiment.

FIG. 6 presents drawings for explaining manufacturing steps of the interposer according to the first embodiment.

FIG. 7 presents drawings for explaining manufacturing steps of the interposer according to the first embodiment.

FIG. 8 presents drawings for explaining manufacturing steps of the interposer according to the first embodiment.

FIG. 9 presents drawings for explaining manufacturing steps of the interposer according to the first embodiment.

FIG. 10 presents drawings for explaining manufacturing steps of the semiconductor package according to the first embodiment.

FIG. 11 presents drawings for explaining manufacturing steps of the semiconductor package according to the first embodiment.

### MODE FOR CARRYING OUT THE INVENTION

The following will describe embodiments of the present invention, with reference to the drawings. However, the present invention is not limited by the following embodiments. Further, in the depiction of the drawings, some of the elements that are same as each other are referred to by using the same reference characters. The terms such as “first” and “second” are not intended to particularly limit the sequential order or configurations and are stipulated for the sake of convenience in explanations.

The positions, sizes, shapes, ranges, and the like of the constituent elements depicted in the drawings may not represent the positions, sizes, shapes, ranges, and the like in reality, for the purpose of facilitating comprehension of the invention. Accordingly, the present invention is not necessarily limited by the positions, sizes, shapes, ranges, and the like disclosed in the drawings.

In the present disclosure, the term “surface” may denote, not only a surface of a plate-like member, but also, with regard to a layer included in a plate-like member, an interface of the layer substantially parallel to a surface of the plate-like member. Further, the terms “upper surface” and “lower surface” denote the surfaces depicted on the upper side and the lower side while a plate-like member or a layer included in a plate-like member is shown in a drawing. In the drawings, the tip end of a Z direction arrow corresponds to an upper surface, whereas the opposite end of the arrow corresponds to a lower surface. Additionally, an “upper surface” and a “lower surface” may be called a “first surface” and a “second surface”.

Further, the term “lateral face” denotes, with regard to a plate-like member or a layer included in a plate-like member, a part corresponding to the thickness of the plate-like member or the layer. In addition, a part of a surface and a lateral face may collectively be referred to as an “end part”.

Further, the term “upper”, “above”, or “over” denotes the direction vertically upward when a plate-like member or a layer is placed horizontally. In addition, the “upper/above/over” direction and the “lower/below/underneath” direction being opposite may be referred to as a “Z-axis plus direction” and a “Z-axis minus direction”. Horizontal directions may be referred to as an “X-axis direction” and a “Y-axis direction”.

Further, the terms “planar shape” and “planar view” refer to a shape that is recognized when a surface or a layer is seen from above. In addition, the terms “cross-sectional shape” and “cross-sectional view” refer to a shape recognized when a plate-like member or a layer is sectioned in a specific direction and seen from a horizontal direction.

Further, the term “central part” denotes a part at the center that is not a peripheral part of a surface or a layer. In addition, a “central direction” denotes a direction from a peripheral part of a surface or a layer, toward the center of the planar shape of the surface or the layer.

As for external connection vias 4 and 14 in the accompanying drawings, terminal ends thereof on the outermost layer side in the Z-axis direction in the drawings of an interposer 100 will each be defined as a top, whereas terminal ends thereof on the inner layer structure 7 side will each be defined as a bottom.

### First Embodiment

### <A Structure of an Onterposer>

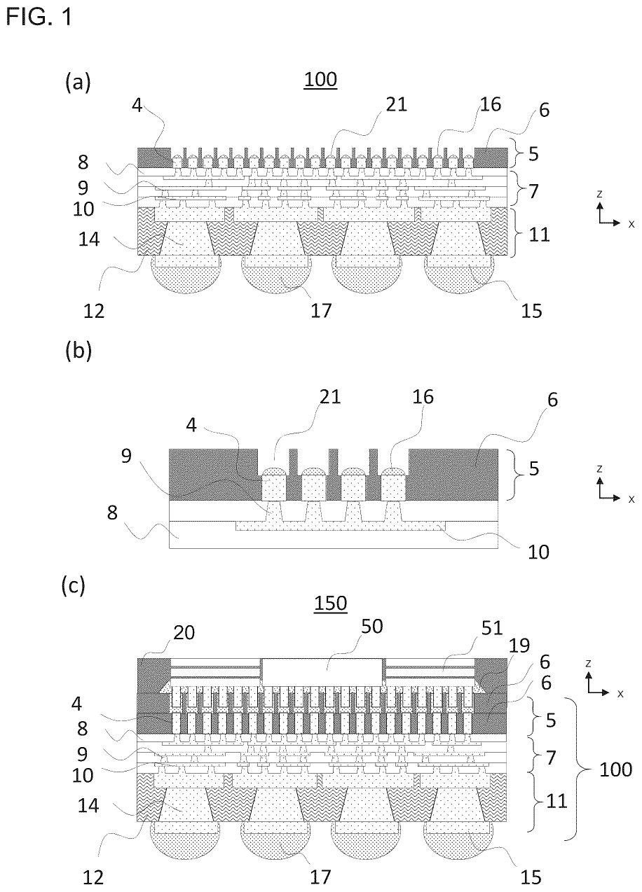

FIG. 1 (a) is an example of a schematic cross-sectional view of the interposer 100 according to a first embodiment of the present invention. FIG. 1(b) is an example of a schematic enlarged cross-sectional view of external connection vias 4 of the interposer 100 according to the first embodiment of the present invention. FIG. 1(c) is an example of a schematic cross-sectional view of a semiconductor package 150 in which semiconductor devices 50 and 51 are installed on the interposer 100 according to the first embodiment.

In the present disclosure, as for the upper and the lower surfaces of the interposer 100, the side on which the semiconductor devices 50 and 51 are installed will be referred to a “first surface side”, whereas the side on which the interposer 100 is connected to a mother board or an FC-BGA will be referred to as a “second surface side”.

Also, in the present embodiment, second connection terminals 17 are provided on the second surface side of a second outer layer structure 11. The second connection terminals 17 serve as connection terminals to an FC-BGA substrate or a mother board.

The interposer 100 shown in FIG. 1(a) is primarily structured with a first outer layer structure 5, the inner layer structure 7, and the second outer layer structure 11.

The first outer layer structure 5 is positioned above the inner layer structure 7, i.e., to the Z-axis plus direction. Further, the first outer layer structure 5 is formed with a second insulating resin layer 6. The second insulating resin layer 6 has formed therein the external connection vias 4 and external connection opening parts 21 penetrating the second insulating resin layer 6 in the Z-axis direction. As shown in FIG. 1(b), the external connection opening parts 21 are provided so that the external connection vias 4 are exposed. Each of the external connection vias 4 is capable of functioning as a pad for an external connection terminal of the first outer layer structure 5. Further, in exposure parts of the external connection vias 4, first connection terminals (solder) 16 may be provided or may be omitted as appropriate. As for the diameter of each of the external connection vias 4 and the diameter of each of the external connection opening parts 21, one of the diameter may be larger than the other, or two diameters may be equal to each other.

The inner layer structure 7 is provided between the first outer layer structure 5 and the second outer layer structure 11.

The inner layer structure 7 includes at least one inner layer wiring layer. The inner layer wiring layer includes a first insulating resin layer 8, a wiring 10 provided on a surface of the first insulating resin layer, and a conductive member connected to the wiring 10 and penetrating the first insulating resin layer in the Z-axis direction. Further, the conductive member penetrating the first insulating resin layer is capable of functioning as vias 9 of the inner layer wiring layer.

The second outer layer structure 11 is positioned below the inner layer structure 7, i.e., to the Z-axis minus direction.

Further, the second outer layer structure 11 is formed with the second insulating resin layer 12. The second insulating resin layer 12 has formed therein the external connection vias 14 penetrating the second insulating resin layer 12 in the Z-axis direction. Each of the external connection vias 14 penetrating the second insulating resin layer 12 is connected to a wiring layer of the outermost layer of the inner layer structure 7 and is capable of functioning as a pad for an external connection terminal of the second outer layer structure 11.

Further, provided on the second surface side of the second outer layer structure 11 are pads 15 for external connection terminals and second connection terminals (solder) 17.

In this situation, as for the thickness of the interposer 100 in the Z-axis direction, it is desirable that a total thickness including the inner layer structure 7, the first outer layer structure 5, and the second outer layer structure 11 is 50 μm or larger.

Further, as for the thicknesses of the first outer layer structure 5 and the second outer layer structure 11 in the interposer 100, although possible thicknesses are not limited to those used in the present embodiment, it is desirable, if the first outer layer structure 5 and the second outer layer structure 11 have higher physical rigidity than the inner layer structure 7, that the sum of the thicknesses of the first outer layer structure 5 and the second outer layer structure 11 is larger than the thickness of the inner layer structure 7. In other words, it is desirable that the first outer layer structure 5 and the second outer layer structure 11 account for a half or more of the total thickness of the interposer 100.

### <A Structure of a Semiconductor Package>

FIG. 1(c) shows the semiconductor package 150 in which the semiconductor devices 50 and 51 are fixed on the first surface side of the interposer 100 explained with reference to FIG. 1(a), by using an underfill 19 and a mold resin 20.

In this situation, although the first connection terminals 16 and the second connection terminals 17 depicted in FIG. 1 are solder, the present embodiment does not limit the type of the solder or the composition of the solder. It is acceptable to use any conductive material that is publicly known. Further, the first connection terminals 16 in FIG. 1 are formed to be flush with the exposure parts of the external connection vias 4 in the first outer layer structure 5. However, possible positional relationships between the first connection terminals 16 and the external connection vias 4 and possible shapes thereof are not limited to those in the present example.

Similarly, although the second connection terminals 17 are formed so as to match the pads 15 for the external connection terminals provided over the external connection vias 14 in the second outer layer structure 11, possible structures are not necessarily limited to the present example.

### <The First Insulating Resin Layer>

When the interposer 100 according to the embodiment shown in FIG. 1(a) is used as an interposer for a SiP having a plurality of semiconductor devices installed, a wiring rule requires at least a fine wiring of L/S=8/8 μm or smaller. For this reason, there is no choice but making at least the thickness of the first insulating resin layer 8 structuring the inner layer structure 7 as thin as 25 μm or smaller.

As a result, there is no choice but to form the inner layer structure 7 to be flexible and to have no physical rigidity, even if the inner layer wiring layer is a multi-layer laminated circuit.

### <The External Connection Opening Parts>

When the interposer 100 according to the embodiment shown in FIG. 1(a) is used as an interposer for a SiP having a plurality of semiconductor devices installed, a structure is achieved in which the pads on which the semiconductor devices are installed and the semiconductor device installation surface have mutually the same flat plane. When assembly is carried out by electrically connecting such flat surfaces to external connection electrodes of the semiconductor devices via the pads, due to weak holding power of the semiconductor devices in the plane direction of the interposer, a problem of an electrical conduction defect may arise because an assembly position misalignment can easily occur before solidification of joining members such as the solder.

To avoid the above problem, the interposer is provided with the external connection opening parts 21 so that it is possible to fit the external connection electrodes of the semiconductor devices therein at the time of installing the semiconductor devices. To ensure that there is a gap for an underfill to enter between each semiconductor device and the semiconductor device installation surface, each of the semiconductor devices is provided with the external connection electrode of which both the diameter and the length are in the range of approximately 20 μm to 25 μm, for example. By using this structure, because the external connection electrodes of the semiconductor devices are fitted into the external connection opening parts 21 of the interposer at the time of installing the semiconductor devices, it is possible to realize a configuration that prevents the misalignments in the plane direction of the interposer.

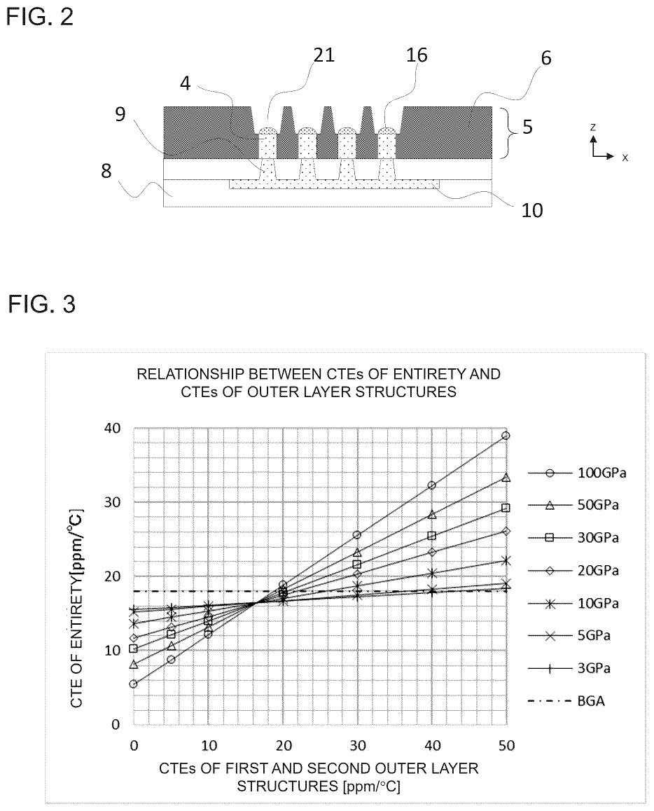

Further, as FIG. 2 shows an example of the shapes of the external connection opening parts 21 of the interposer 100, the external connection opening parts 21 are each formed to have a tapered shape so as to satisfy: the opening diameter at the top (the semiconductor device installation surface side) of each external connection opening part 21 >the opening diameter at the bottom of each external connection opening part 21. By using this structure, it is possible to assist installation positional alignment of a semiconductor device installer and to thus realize a configuration that simplifies the positional alignment at the time of installing the semiconductor devices.

Furthermore, by using the solder for the first connection terminals formed at the exposure parts of the external connection vias 4 inside the external connection opening parts 21, it is possible to fill the gaps which may be present between the external connection electrodes and the external connection opening parts 21 after the installation of the semiconductor devices and to thus realize enhancement of connection reliability.

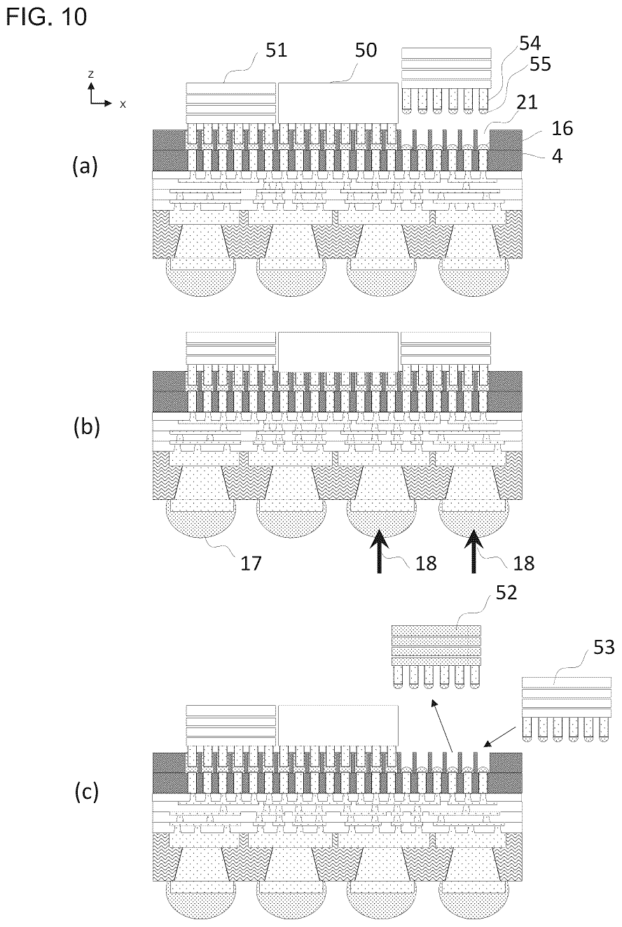

Furthermore, by ensuring that joint parts between the external connection vias 4 of the interposer 100 and external connection electrodes 54 of the semiconductor devices 50 to 53, which are electrically connected via either the first connection terminals 16 or connection terminals 55 of the semiconductor devices, are positioned inside the external connection opening parts 21 in the thickness direction of the interposer 100, it is possible to fix the joint parts with the second insulating resin layer 6 and to thus realize enhancement of electrical connection reliability (see FIG. 10 for the elements 52 to 55).

### <The CTEs and Elastic Moduli of the Outer Layer Structures>

For the second insulating resin layer structuring the first outer layer structure 5 and the second outer layer structure 11, it is desirable to select from among various non-photosensitive insulating resins containing a filler. Further, it is even more desirable that the second insulating resin layer is a non-photosensitive resin layer containing a filler and that the selection is made from among prepregs, built-up resins, and mold resins having an elastic modulus of 5 GPa or higher and a Coefficient of Thermal Expansion (CTE) of 20 ppm/° C. or lower.

The first insulating resin layer that is applicable to the inner layer structure 7 according to the present embodiment uses either a photosensitive insulating resin or a built-up resin, which is, with regard to general physical properties of the material, a material having low elasticity and a high CTE, such as a CTE is in the range of 20 ppm/° C. to 80 ppm/° C. and an elastic modulus in the range of 1.5 GPa to 10 GPa inclusive.

Accordingly, when an interposer is formed by using only the abovementioned materials, the CTE would be lower than the CTE of the FC-BGA, which is 18 ppm/° C. In that situation, it would be difficult to realize an interposer capable of achieving a buffer function for the low CTE of the semiconductor devices.

In this regard also, in the present embodiment, by making a selection from among mold resins, prepregs, and built-up resins having a CTE of 20 ppm/° C. or lower and a high elastic modulus of 5 GPa or higher, with respect to the second insulating resin layer used for the first outer layer structure 5 and the second outer layer structure 11, it is possible to configure the CTE of the interposer as a whole to be equal to or lower than the CTE of the FC-BGA, which is in the range of 15 ppm/° C. to 30 ppm/° C.

When the CTE of the second insulating resin layer used for the first outer layer structure 5 and the second outer layer structure 11 is configured to be equal to or lower than 20 ppm/° C., an advantageous effect is achieved where it is possible to reduce the CTE of the interposer 100, as a whole, as described below.

FIG. 3 presents simulation results of the present invention on a relationship between CTEs of the interposer as a whole having a total thickness of 50 μm, CTEs of the materials used in the first outer layer structure and the second outer layer structure, and elastic moduli. The Y-axis expresses the CTEs of the interposer as a whole, while the X-axis expresses the CTEs of the first and the second outer layer structures. The following simulation conditions were used. It should be noted that the CTEs and the elastic moduli of the first outer layer structure and the second outer layer structure were calculated as factors having an equal value.

### The First Outer Layer Structure

Thickness: 20 μm; Volume ratio of a copper wiring was fixed at 10%; CTEs and elastic moduli were factors.

### The Second Outer Layer Structure

Thickness: 20 μm; Volume ratio of a copper wiring was fixed at 30%; CTEs and elastic moduli were factors.

### The Inner Layer Structure

Thickness: 10 μm; CTE: 65 ppm/° C.; Elastic modulus: 2 GPa; Copper wiring thickness: 2 μm; Volume ratio of a copper wiring: 85%.

### Total Thickness of the Interposer: 50 μm.

Results of the simulation carried out under the above conditions are presented in the chart of FIG. 3. More specifically, as apparent from FIG. 3, by using the first outer layer structure 5 and the second outer layer structure 11 of which the CTEs are 20 ppm/° C. or lower, it is possible to configure the CTE of the interposer 100 as a whole to be lower than that of a conventional FC-BGA substrate.

The following is also observed: the higher the elasticity of the materials for the first outer layer structure 5 and the second outer layer structure 11 is, the higher effect is achieved in reducing the CTE of the interposer as a whole.

Consequently, it became clear that it is possible to effectively reduce the CTE of the interposer as a whole when the elastic modulus of the first outer layer structure 5 and the second outer layer structure 11 is 5 GPa or higher. It is desirable that the CTE is selected from 20 ppm/° C. or lower and that the elastic modulus is selected from 5 GPa or higher.

### <Configurations and Copper Volume Ratios of the Outer Layer Structures>

Of the interposer 100 according to the embodiment shown in FIG. 1(a), the external connection vias 4, the external connection vias 14, and the pads 15 of the first outer layer structure 5 and the second outer layer structure 11 have a function of electrically connecting the first connection terminals 16 and the second connection terminals 17 to the wiring of the inner layer structure 7. For this reason, the first outer layer structure 5 and the second outer layer structure 11 are basically formed with connection paths in the Z direction.

In contrast, the inner layer structure 7 uses the wiring suitable for the fine design to realize the routing of the wiring in the Z-axis direction and in the direction orthogonal to the Z-axis direction, i.e., the horizontal directions.

As for the conductive member used in the interposer of the present embodiment, copper is used in principle. However, because the CTE of copper is relatively high being 16 ppm/° C., when the first outer layer structure 5 and the second outer layer structure 11 have a high copper volume ratio, it would be difficult to reduce the CTE of the interposer 100 as a whole.

For this reason, it is preferable that the copper volume ratio of the first outer layer structure 5 and the second outer layer structure 11 is 80% or lower. It is more preferable that the copper volume ratio is 50% or lower. It is even more preferable that the copper volume ratio is 30% or lower.

### <An Advantageous Effect of the Outer Layer Structures: Inhibiting Cracks>

As mentioned above, it would be difficult to strengthen the physical rigidity of the inner layer structure 7 by using a filler or glass cloth filling. The inner layer structure 7 is therefore physically fragile (having a low tensile strength and a low elongation value). As a result, a crack may occur in the inner layer structure 7 due to temperature changes or the like. It is feared that a failure leading to a disconnection of the wiring layer may occur. In this regard, the interposer 100 according to the present embodiment is able to enhance reliability of the inner layer structure 7 having the fine wiring structure, by having the first outer layer structure 5 and the second outer layer structure 11 formed on the entirety of both of the surfaces of the inner layer structure 7.

In relation to the above, it has been discovered that, if the first outer layer structure 5 and the second outer layer structure 11 were formed only partially on the upper surface and the lower surface of the inner layer structure 7, a crack would occur on the inner layer structure 7 due to a deformation or a stress concentration.

Consequently, it is necessary to form the first outer layer structure 5 and the second outer layer structure 11 on the entirety of both of the surfaces of the inner layer structure 7.

In the present embodiment, the physical properties and the specific materials used for the first outer layer structure 5 and the second outer layer structure 11 are not particularly prescribed. However, it is desirable that the CTEs of the first outer layer structure 5 and the second outer layer structure 11 are close to each other.

### <Another Advantageous Effect of the Outer Layer Structures: Assemblability>

In the present embodiment, providing the first outer layer structure 5 and the second outer layer structure 11 on both of the surfaces of the inner layer structure 7 is also suitable from a viewpoint of assemblability of the semiconductor devices. As mentioned above, if the second outer layer structure 11 were provided only on the lower surface of the inner layer structure 7, the interposer 100 would warp from the heat applied at the time of the assembly, due to the difference in the CTEs between the materials. Because such warping is directly linked to a connection failure of the semiconductor devices, it is desirable to minimize the warping.

In the interposer 100 according to the present embodiment, because the inner layer structure 7 having a relatively high CTE and a relatively low elastic modulus is sandwiched between the first outer layer structure 5 and the second outer layer structure 11 that are provided on both of the surfaces and made of the material having a low CTE and high elasticity, it is possible to effectively inhibit thermal deformations of the inner layer structure 7.

Consequently, it is possible to sufficiently inhibit warping of the interposer 100 even during the assembling step of the semiconductor devices 50 and 51.

In addition, particularly because it is possible to sufficiently inhibit warping of the interposer 100 even during the assembling step of the semiconductor devices 50 and 51, the external connection opening parts 21 function effectively and make it possible to prevent the assembly position misalignment between the semiconductor devices 50, 51 and the interposer 100. In the event where warping of the interposer 100 were caused by excessive heat at the time of the assembly, the external connection electrodes 54 of the semiconductor devices 50 and 51 would come out of the external connection opening parts 21 of the interposer 100, and there would be an assembly position misalignment between the semiconductor devices 50, 51 and the interposer 100.

### <A Configuration of the Inner Layer Structure>

The inner layer structure 7 depicted in FIG. 1(a) and FIG. 1(c) is structured with the first insulating resin layer 8, the wiring 10, and the vias 9 in the inner layer wiring layer that penetrate the first insulating resin layer 8. The thicknesses of constituent elements of the inner layer wiring layer, the quantity of the layers, the wiring layer pattern, the shapes of the vias, the direction of tapering of the vias, the quantity of the vias, and the like are not limited by the present embodiment.

As for the inner layer structure 7, the inner layer wiring layer may be formed as a single layer or a plurality of layers. The quantity of the layers and the thicknesses thereof are not limited by the present embodiment. However, in the interposer 100, it is desirable that the inner layer wiring layer is formed as a plurality of layers, when the use in a SiP is expected.

### <A Wiring Rule for the Inner Layer Wiring Layer>

As for the inner layer wiring layer of the inner layer structure 7 shown in FIG. 1(a), it is desirable that the wiring design rule of the wiring 10 is a wiring design rule that is applicable to an inter-chip fine connection. It is preferable that L/S=15/15 μm or smaller is satisfied. It is more preferable that L/S=10/10 μm or smaller is satisfied. It is even more preferable that L/S=8/8 μm or smaller is satisfied. When L/S is 15/15 μm or larger, the values are equivalent to the wiring rule for a conventional FC-BGA and are therefore not suitable for assembly of HBM or the like.

### <The Insulating Resin Layers in the Outer Layer Structures: Non-Photosensitive Resin>

For the second insulating resin layers 6 and 12 being constituent elements of the first outer layer structure 5 and the second outer layer structure 11 in FIG. 1(a), it is possible to select, as a non-photosensitive insulating resin, from among epoxy-phenol resins, epoxy-phenol ester resins, epoxy-cyanate resins, cyanate resins, benzocyclobutene, polyimide, polybenzoxazole, and the like. Although It is also acceptable to have a filler or glass cloth contained, it is desirable to set the content amount of the filler or the glass cloth to a value that does not hinder the formation of a fine wiring of L/S=8/8 μm or smaller.

### <The Insulating Resin Layer in the Inner Layer Structure: Photosensitive Resin>

As a material of the first insulating resin layer 8 being a constituent element of the inner layer structure 7 in FIG. 1(a), it is possible to adopt a publicly known technique of using, as a photosensitive insulating resin, benzocyclobutene, polyimide, polybenzoxazole, an epoxy resin, epoxy acrylate, acrylate, or the like. In the situation where the first insulating resin layer 8 according to the present embodiment requires at least the formation of a fine wiring of L/S=8/8 μm or smaller, it is desirable to use a photosensitive insulating resin that is beneficial in the formation of the fine wiring.

### <The Insulating Resin Layer in the Inner Layer Structure: Advantages of the Photosensitive Resin>

When the first insulating resin layer 8 uses a photosensitive insulating resin, it is possible to form small vias each having a diameter of 20 μm or smaller, with a positional precision level of ±3 μm or smaller through photolithography. Accordingly, it is possible to maximize the quantity of the semiconductor devices to be installed on the interposer and to also maximize the quantity of the connection vias.

Photosensitive insulating resins have an advantage where the vias can be formed all at once while the via formation period is not dependent on the quantity of the vias.

### <The Insulating Resin Layer in the Inner Layer Structure: Non-Photosensitive Resin>

It is also acceptable to use a non-photosensitive insulating resin, as a material of the first insulating resin layer 8. The material may be selected from among an epoxy-phenol resin, an epoxy-phenol ester resin, an epoxy-cyanate resin, a cyanate resin, benzocyclobutene, polyimide, polybenzoxazole, and the like. Further, It is also acceptable to have a filler or glass cloth contained.

### <The Insulating Resin Layer in the Inner Layer Structure: Advantages of the Non-Photosensitive Resin>

When the inner layer structure uses a non-photosensitive insulating resin, because it is possible to select an insulating resin having high elasticity, there is an advantage that it is possible to give high rigidity to the interposer.

<The thickness of the insulating resin layer in the inner layer wiring layer>

It is desirable that the thickness of the first insulating resin layer 8 is 25 μm or smaller. In this situation, the thickness of the first insulating resin layer 8 denotes the thickness of the resin positioned between copper wiring patterns of the upper and the lower layers. When the thickness of the first insulating resin layer is 25 μm or larger, it would be difficult to form small-diameter vias each having a diameter of 20 μm or smaller, and increasing wiring density would be troublesome. It is more preferable that the thickness of the first insulating resin layer is 15 μm or smaller. It is even more preferable that the thickness thereof is 10 μm or smaller.

Further, the thickness of the first insulating resin layer 8 may be adjusted as appropriate, depending on the wiring rule to be applied and impedance matching of circuits.

### <The Diameter of the Vias in the Inner Layer Wiring Layer>

It is desirable that the diameter of the vias 9 in the inner layer wiring layer is 40 μm or smaller. In this situation, the diameter of the vias 9 refers to a maximum diameter part. When the diameter of the vias 9 is 40 μm or larger, the endeavor to raise the wiring density would be hindered. It is more preferable that the diameter is 30 μm or smaller. It is even more preferable that the diameter is 20 μm or smaller, because it is possible to make contribution to the endeavor to raise the wiring density.

### <The Thickness of the Wiring in the Inner Layer Wiring Layer>

It is desirable that the thickness of the wiring 10 is 15 μm or smaller. It is more preferable that the thickness is 10 μm or smaller. It is even more preferable that the thickness is 8 μm or smaller. When the thickness is 15 μm or larger, it would be difficult to form a fine wiring satisfying L/S=15/15 μm or smaller, although circumstances may depend on the resist used for a photolithography purpose. It is desirable that the thickness of the wiring is adjusted as appropriate depending on the wiring rule to be applied and impedance matching of circuits.

### <Wiring Materials for the Inner Layer Wiring Layer>

The material used for the wiring 10 may include: single-element metal of copper, aluminum, nickel, silver, gold, tungsten, iron, niobium, tantalum, titanium, or chrome; and an alloy thereof or one or more added elements. Further, a layered structure may be formed by using any of the various types of materials. Alternatively, it is also acceptable to use a conductive paste containing any of those materials, carbon, a conductive resin, or the like.

For example, when a metal layer is to be formed on the first insulating resin layer 8 through sputtering, it is a common practice to form a single-element layer or an alloy layer using titanium, chromium, nickel, and/or the like, before the formation using copper. It is also acceptable to form a layer through non-electrolytic copper plating or non-electrolytic nickel plating on the upper surface of the first insulating resin layer 8. Forming the wiring 10 through electrolytic copper plating is common, convenient, and inexpensive and is therefore desirable.

### <The Thickness of the Interposer>

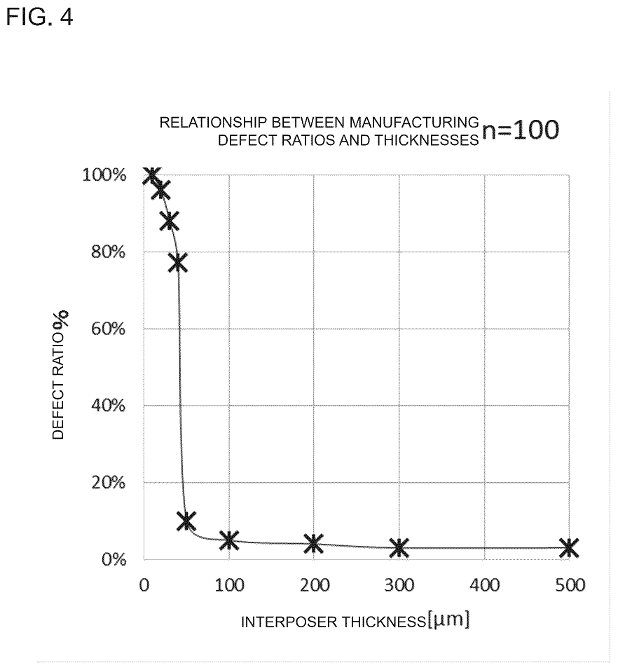

It is desirable that the thickness of the interposer 100 according to the present embodiment is at least 50 μm or larger. As shown in FIG. 4, when the thickness is smaller than 50 μm, the interposer 100 itself would not have sufficient rigidity. As a result, an extremely large number of defects might occur in a connection terminal formation step, an electrical inspecting step, and a semiconductor device installation step that will follow.

According to the present embodiment, it is possible to carry out an electrical inspection on the interposer alone, at a stage prior to the installation of the semiconductor devices. Accordingly, it is possible to express the yield of the interposers after the manufacturing/inspection described in Formula (1) as below:

$$( {Y}_{INTERPOSER} ) = 100 \% \qquad ( 4 )$$

Consequently, it is possible to make contribution to improving the manufacturing yield (Y_{TOTAL}) of the SiPs.

### Description of an Outline of the Manufacturing Steps

An outline of a method for manufacturing the interposer according to the present embodiment includes the steps presented below.

At first, a support substrate is prepared, and subsequently, it is possible to obtain the interposer by performing the following steps:
a first step of forming the first outer layer structure on the support substrate;
a second step of forming the inner layer structure on the first outer layer structure;
a third step of forming the second outer layer structure on the inner layer structure;
a fourth step of peeling the first outer layer structure and the support substrate from each other; and
a fifth step of forming the external connection opening parts 21 on the outermost layer of the first outer layer structure.

When the formation of the first outer layer structure and the second outer layer structure is completed, it is possible to ensure sufficient rigidity with the interposer alone, without the support substrate. For this reason, in the subsequent steps, it is possible to manufacture the interposer or a semiconductor package peeled off from the support substrate.

Because there is no support substrate, it is possible to apply surface processing, to form solder bumps, and/or to form projection electrodes, on the external connection terminals exposed from both of the two surfaces of the substrate. Thus, it is possible to form the first and the second connection terminals on both of the two surfaces of the interposer.

### A DETAILED DESCRIPTION OF A MANUFACTURING METHOD

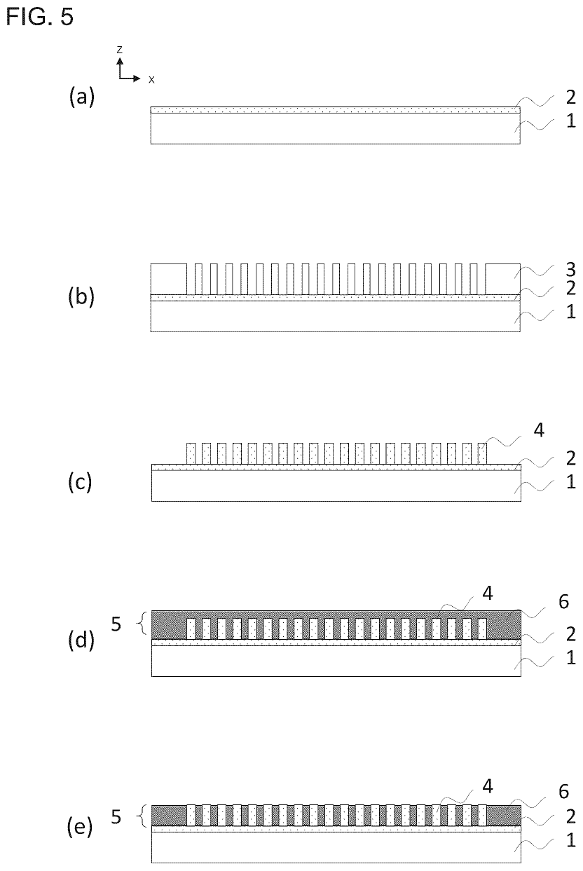

The following will describe details of manufacturing methods of the interposer and the semiconductor package, with reference to FIGS. 5 to 9.

### <A Support Substrate Preparation Step>

As shown in FIG. 5(a), to begin with, a support substrate 1 is prepared. As the support substrate 1, for example, it is possible to use a product obtained by providing a laser peel-off layer on a glass substrate, and further providing the metal layer 2 on the laser peel-off layer. The metal layer 2 may be formed through non-electrolytic plating or sputtering. Alternatively, it is also acceptable to use a support substrate obtained by forming a carrier copper foil as the metal layer 2 on a Copper Clad Laminate (CCL) substrate, via a prepreg. In this situation, the carrier copper foil has a three-layer structure including a carrier copper foil, a peel-off layer, and an extremely thin copper foil and is a copper foil that can physically be peeled off easily at the interfaces of the peel-off layer. Possible types of the support substrate are not limited to the above examples. It is possible to use any of various types of substrates that are publicly known.

FIG. 5(b) shows a substrate on which a resist pattern 3 for a photolithography purpose is formed as a result of forming a resist layer for a photolithography purpose on the metal layer 2 and subsequently performing a patterning process. The thickness of the resist for the photolithography purpose is determined as appropriate in view of the height of the pads to be formed. In the present embodiment, the resist for the photolithography purpose in a liquid form is applied to have a thickness of 70 μm, so that a pattern is formed by forming circular cylindrical pads each having a diameter of 25 μm with a 60-μm pitch, as the pads for the first connection terminals.

FIG. 5(c) shows a result of forming the external connection vias 4 through electrolytic copper plating after the step shown in FIG. 5(b) and subsequently peeling off the resist for the photolithography purpose. The external connection vias 4 each having the circular cylindrical shape function as the pads. In the present embodiment, the external connection vias 4 are formed through copper plating with an average height of 25 μm in the Z-direction.

FIG. 5(d) is a drawing showing a result of forming a non-photosensitive insulating resin structuring the first outer layer structure 5. In the present embodiment, the second insulating resin layer 6 including a non-photosensitive resin uses a non-photosensitive resin containing at least a filler, which may desirably be selected from among prepregs, built-up resins, and mold resins having an elastic modulus of 5 GPa or higher and a CTE of 20 ppm/° C. or lower. In the present embodiment, the second insulating resin layer 6 is formed through vacuum lamination by using a film-like mold resin having a thickness of 30 μm. Possible types, thicknesses, and forming methods of the non-photosensitive resin are not limited to those used in the present embodiment. It is possible to select a material and a forming method as appropriate.

FIG. 5(e) shows a result of shaving the second insulating resin layer 6 with a grinder and causing the external connection vias 4 to be exposed, which serve as pads for the first outer layer structure 5. Possible methods for making the pads exposed are not limited to the method used in the present embodiment. It is also acceptable to use polishing using CMP, buff polishing, belt polishing, or a fly cutting method that is publicly known. Thus, in the present embodiment, the external connection vias 4 serving as the pads have been formed in the second insulating resin layer 6 of the first outer layer structure 5. In the present embodiment, the external connection vias 4 are formed so as to have, after the pads are exposed, an average height of 25 μm in the Z-direction.

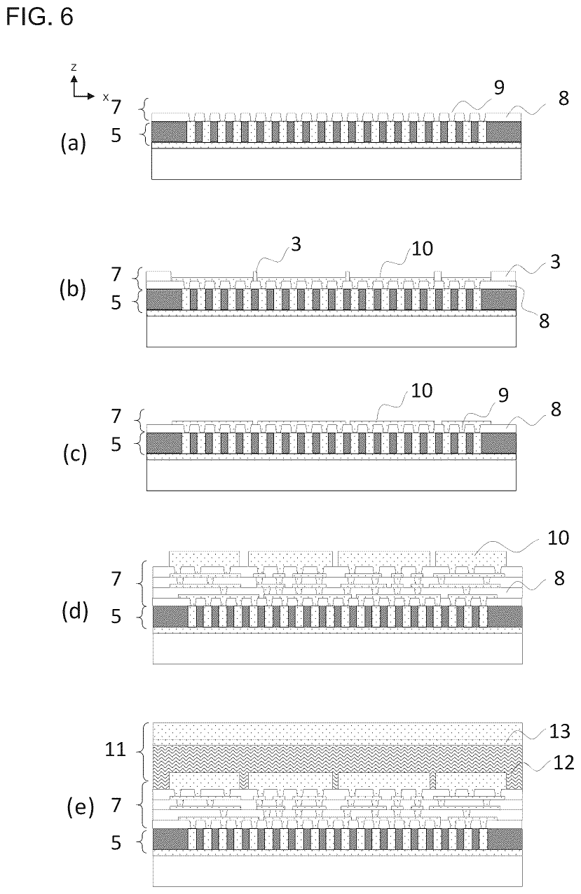

FIG. 6(a) shows a result of having the first insulating resin layer 8 of the inner layer structure 7 formed over the first outer layer structure 5 and forming the vias 9. In the present embodiment, the first insulating resin layer 8 is formed to have a thickness of 6 μm by using a photosensitive insulating resin, and the vias 9 are each formed to have a diameter of 15 μm.

FIG. 6(b) shows a result of forming a seed metal layer (not shown) on the first insulating resin layer 8, subsequently forming the resist pattern 3 for the photolithography purpose, and further forming the vias 9 and the wiring 10 of the inner layer wiring layer through electrolytic plating. In the present embodiment, as the seed metal layer, a layer of Ti/Cu=50 nm/300 nm is formed through sputtering, whereas the resist for the photolithography purpose is formed to have a thickness of 5 μm. Thus, after the resist pattern 3 for the photolithography purpose satisfying L/S=2/2 μm has been formed, the wiring 10 having a thickness of 2 μm is formed through electrolytic plating.

FIG. 6(c) is a drawing showing a result of peeling off the resist pattern 3 for the photolithography purpose, subsequently removing the seed metal layer, and forming the first insulating resin layer 8 and the inner layer wiring layer including the vias 9 and the wiring 10.

In this situation, possible methods for forming the wiring and possible method for forming the insulating resin layers are not limited to the methods of the present embodiment. It is possible to select forming methods, as appropriate.

FIG. 6(d) shows the inner layer structure 7 in which the wiring 10 and the first insulating resin layer 8 are each stacked in four layers, by further repeatedly performing the steps shown in FIGS. 6(f) to 6(h) three times. The thickness of each of the first insulating resin layers 8 is 6 μm, whereas the thickness of each of the wirings 10 is 2 μm. The thickness of the wiring 10 for the outermost layer is 12 μm. As a result, the thickness of the inner layer structure 7 is 36 μm.

FIG. 6(e) is a drawing for explaining steps for forming the second outer layer structure 11. At first, above the inner layer structure 7, a prepreg and a copper foil having a carrier are formed through lamination pressing, so as to serve as the second insulating resin layer 12 in the second outer layer structure 11. In the present embodiment, the copper foil having the carrier which has a carrier foil thickness of 18 μm and a thin copper foil side thickness of 3 μm is used, while a 3-μm thin copper foil 13 is positioned on the prepreg side. The prepreg having a thickness of 70 μm is used.

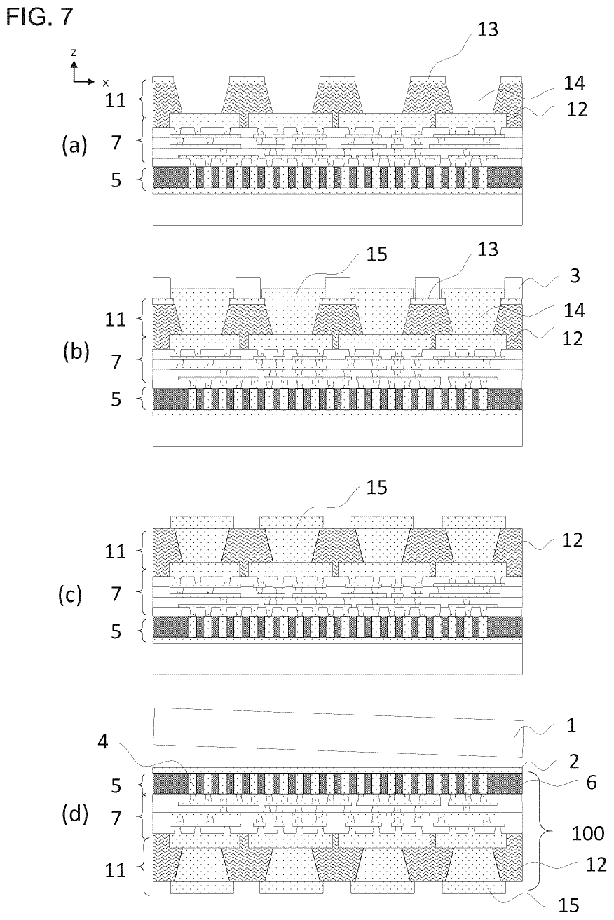

FIG. 7(a) shows a result of peeling off and removing the carrier foil from the copper foil with the carrier and further forming the external connection vias 14 in the second outer layer structure 11 by using a CO2 laser. After that, a desmearing process is performed on laser opening parts, and further, non-electrolytic copper plating having a thickness of 0.6 μm is formed (not shown) onto the via parts, through non-electrolytic copper plating. In the present embodiment, the vias each having a diameter of 60 μm are formed with a 150-μm pitch.

FIG. 7(b) shows a result of forming the resist pattern 3 for the photolithography purpose, and subsequently forming the pads 15 through electrolytic copper plating. In the present embodiment, the electrolytic copper plating layer is formed so that the pads 15 have a thickness of 18 μm.

FIG. 7(c) is a drawing showing a result of removing the resist pattern 3 for the photolithography purpose, and subsequently, removing the thin copper foil 13 and the non-electrolytic copper plating layer through etching, so as to form the second outer layer structure 11. In the present embodiment, the pads 15 having a diameter of 75 μm and a pad thickness of 15 μm are formed on the second outer layer structure with a 150-μm pitch.

FIG. 7(d) is a drawing showing FIG. 7(c) upside down and depicts a step of removing the support substrate 1. It is possible to obtain the interposer 100 in which the first outer layer structure 5 is provided with the external connection vias 4, while the second outer layer structure 11 is provided with the pads 15 being exposed, by providing a protection sheet (not shown) on a surface of the second outer layer structure 11, subsequently removing the metal layer 2 through etching, and further removing the protection sheet (not shown) from the second outer layer structure 11.

In the present embodiment, on both of the surfaces of the inner layer structure 7, the first outer layer structure 5 and the second outer layer structure 11 selected from among materials having high elasticity and a low CTE are formed, and the interposer 100 is thus formed to have a total thickness of 50 μm or larger. The interposer formed in this manner has rigidity that allows the interposer to be transported alone. Further, because the supporting member has been removed from the interposer, both of the surfaces of the interposer are exposed. Thus, it is possible to form the first connection terminals 16 and the second connection terminals 17 on the upper and the lower surfaces of the interposer.

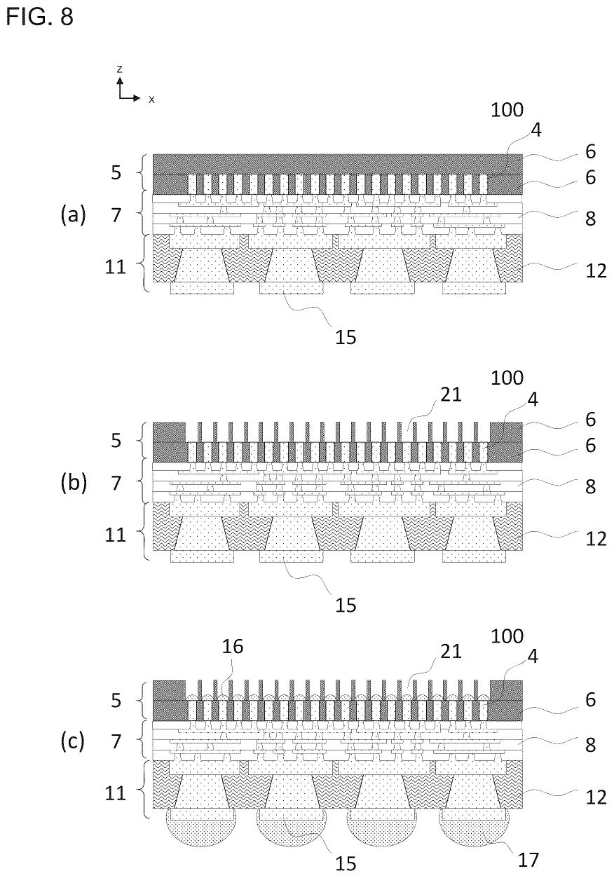

FIG. 8(a) is a drawing showing a result of further stacking another second insulating resin layer 6 on the second insulating resin layer 6 shown in FIG. 7(d). In the present embodiment, the thickness of the first outer layer structure 5 corresponds to a sum of the thicknesses of the second insulating resin layer 6 in FIG. 7(d) and the second insulating resin layer 6 stacked in the present step. In the present embodiment, the first outer layer structure 5 is formed to have a thickness of 50 μm in the Z direction.

FIG. 8(b) is a drawing showing a result of forming the external connection opening parts 21 above the second insulating resin layer 6 stacked in FIG. 8(a). To form the external connection opening parts 21, a laser may be used. Further, by adjusting laser processing conditions as appropriate, it is possible to adjust taper angles of the external connection opening parts 21.

FIG. 8(c) shows a step of performing surface processing on the external connection vias 4 exposure parts of the external connection opening parts 21 that were formed in FIG. 8(b) and on the pads 15 serving as external connection terminals of the second outer layer structure 11.

After the surface processing, it is possible to form solder on both of the pad layers. As for the method for forming the solder also, it is possible to adopt any of publicly-known methods, as appropriate, such as a screen printing method, a ball mounting method, an electroplating method, or a method by which melted solder is used as a filling after a resist pattern for a photolithography purpose is formed. In the present embodiment, as the surface processing, non-electrolytic Ni/Pd/Au is applied to both surfaces, and solder is formed on both of the upper and the lower surfaces by using a solder ball method. In this manner, is possible to obtain the interposer 100 according to the present embodiment in which the first connection terminals 16 and the second connection terminals 17 are formed on the first outer layer structure 5 and the second outer layer structure 11.

In the method for manufacturing the interposer 100 according to the present embodiment shown in FIGS. 5(a) to 9(b), the first outer layer structure 5, the inner layer structure 7, and the second outer layer structure 11 are formed in the stated order; however, possible embodiments are not limited to this sequential order, and it is also acceptable to select a method by which the formation is carried out in the reversed order. In other words, the interposer 100 of the present embodiment may be manufactured in the following order: A step of preparing the support substrate 1 and a step of forming the metal layer 2; followed by a step of forming the second outer layer structure 11, a step of forming the inner layer structure 7; and a step of forming the first outer layer structure 5.

Explanations of the specific procedure will be omitted because the same steps as those shown in FIGS. 5(a) to 7(d) and FIGS. 8(b) to 9(b) will be used. However, differences lie in that the second insulating resin layer 6 of the first outer layer structure 5 shown in FIG. 8(a) is stacked at once as a single layer of the second insulating resin layer 6 having a large resin thickness, instead of the two layers and that the sequential order for forming the pads 15 comes after removal of the support substrate 1. Through the present steps, it is possible to obtain the interposer 100 of the present embodiment.

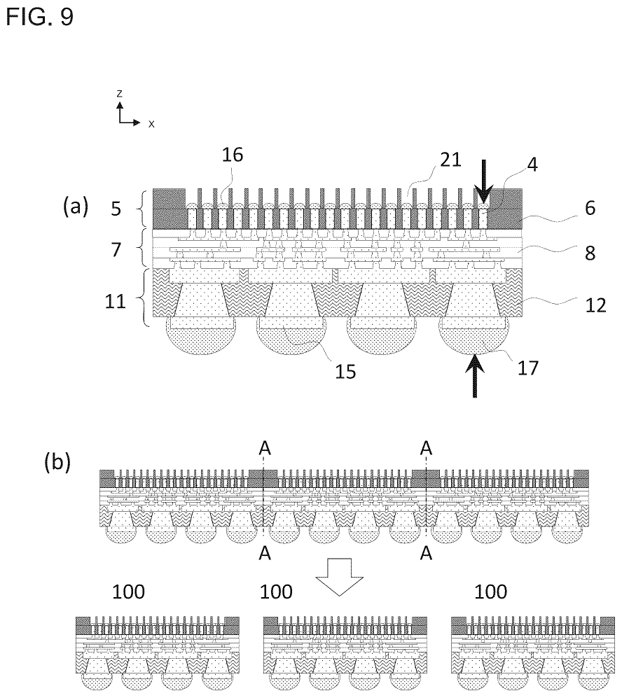

FIG. 9(a) shows a step of performing an electrical inspection on the interposer 100, by simultaneously bringing electric inspection needles into contact with the first connection terminals 16 and the second connection terminals 17 formed on both of the surfaces of the interposer 100.

The following will describe the specific electrical inspection and a manufacturing procedure utilizing a result thereof.
1) A first inspecting step of performing the electrical inspection on the interposer through the connection terminals;
2) A first judging step of judging whether the interposer is good or not, on the basis of a result of the first inspecting step;
3) A temporary connecting step of installing the semiconductor devices on an interposer determined to be “good” in the first judging step;
4) A second inspecting step of performing an electrical inspection on the semiconductor package resulting from the temporary connection;
5) A second judging step of judging whether the semiconductor package is good or not, on the basis of a result of the second inspecting step; and
6) A mending step of repairing and/or replacing the assembly, with respect to a semiconductor package determined to be “not good” in the second judging step.

Further, in addition to the manufacturing procedure described above, it is also acceptable to perform the following procedure.
7) A third inspecting step of performing an electrical inspection on the semiconductor package after the mending step;
8) A third judging step of judging whether the semiconductor package is good or not, on the basis of a result of the third inspecting step; and
9) A fixing step of supplying an underfill to a gap between the semiconductor devices and the interposer in the semiconductor package determined to be “good” in the third judging step.

FIG. 9(b) is a drawing showing a step of cutting to obtain individual interposers by dicing an original panel sheet into individual pieces at locations A-A, the original panel sheet having a plurality of interposers according to the present embodiment contiguously formed in a grid formation. In this manner, the interposer 100 according to the present embodiment has been manufactured.

### A Method for Installing the Semiconductor Devices

Next, a method for manufacturing a semiconductor package by installing the semiconductor devices on the interposer according to the present embodiment will be explained, with reference to FIG. 10.

FIG. 10(a) is a cross-sectional view showing an outline of a step of manufacturing the semiconductor package by installing the semiconductor devices 50 and 51 on the interposer. The interposer used in the present embodiment has already undergone an electrical inspection as a stand-alone interposer and has been confirmed to be a good product.

As for the method for assembling the semiconductor devices, for example, it is possible to use a publicly-known assembling technique such as mass reflow or Thermal-Compression Bonding (TCB). When TCB is used, there is little chance of having a CTE mismatch that may be caused by heating the interposer at a high temperature, during the installation of the plurality of semiconductor devices or during a reflow process.

Further, because the interposer 100 is provided with the external connection opening parts 21, the external connection electrodes 54 of the semiconductor devices fit into the external connection opening parts 21 when the semiconductor devices are installed. Thus, it is possible to prevent positional misalignments during the installation of the plurality of semiconductor devices or during a reflow process.

In addition, when the external connection opening parts 21 each have a circular shape, stress is better dispersed than when the external connection opening parts 21 each have a square shape.

Moreover, by configuring the cross-sectional shape of each of the external connection opening parts 21 to be a tapered shape of which the diameter gradually decreases along the thickness direction starting with the semiconductor device installation surface side of the interposer 100, it is possible to correct the installation positions with the tapered shapes even when an installation position misalignment has occurred in the semiconductor devices due to a semiconductor device installer or the like. It is therefore possible to install the semiconductor devices with a higher level of positional precision.

In addition, when either the first connection terminals 16 or the connection terminals 55 of the semiconductor devices use a conductive adhesive agent that is fluid at temperatures equal to or higher than room temperature, it is possible, after the semiconductor devices are installed, to fill the gap between the external connection opening parts 21 and the external connection electrodes 54 of the semiconductor devices with the conductive adhesive agent and to strengthen the joint parts between the external connection vias 4 of the interposer 100 and the external connection electrodes 54 of the semiconductor devices. It is therefore possible to enhance connection reliability. Furthermore, the joint parts between the external connection vias 4 of the interposer 100 and the external connection electrodes 54 of the semiconductor devices are strengthened by the second insulating resin layer 6 having high elasticity via the conductive adhesive agent. It is therefore possible to further enhance connection reliability. As the conductive adhesive agent, it is possible to select solder or a paste containing metal particles. For the semiconductor package 150 of the present invention, solder is selected.

Further, in an underfill step according to the present embodiment, it is desirable to use a capillary underfill, instead of using a Non-Conductive Film (NCF) or a Non-Conductive Paste (NCP). The reason is that, when a capillary underfill is used, even if a defect is found in a semiconductor device at a subsequent electrical inspection, it is possible to easily replace the semiconductor device found to be defective.

Next, FIG. 10(b) is a drawing showing an electrical inspection performed on a SiP serving as the semiconductor package according to the present embodiment. Through the electrical inspection performed by bringing testing probes 18 into contact with the second connection terminals 17, it is possible to inspect an “assembly yield (YASSEMBLY)” including the individually installed semiconductor devices. It is therefore possible to identify an assembly defect or a defect in the semiconductor devices.

FIG. 10(c) is a schematic cross-sectional view showing a step of partially removing a semiconductor device 52 that was identified to have an assembly defect or a defect in the previous step and replacing the removed device with a good semiconductor device 53. In the present embodiment, the installed semiconductor devices do not go through a chip fixation process that uses a mold resin or an underfill. It is therefore possible to partially correct an assembly defect location or a defective semiconductor device. After the correction, it is possible to achieve (Y_{ASSEMBLY})=100%.

Consequently, by using the interposer according to the present embodiment, it is possible to make contribution to improving the SiP construction total yield (YTOTAL), regardless of the quantity N of the chips to be integrated. It is possible to carry out the correction by performing steps reversing the TCB assembly.

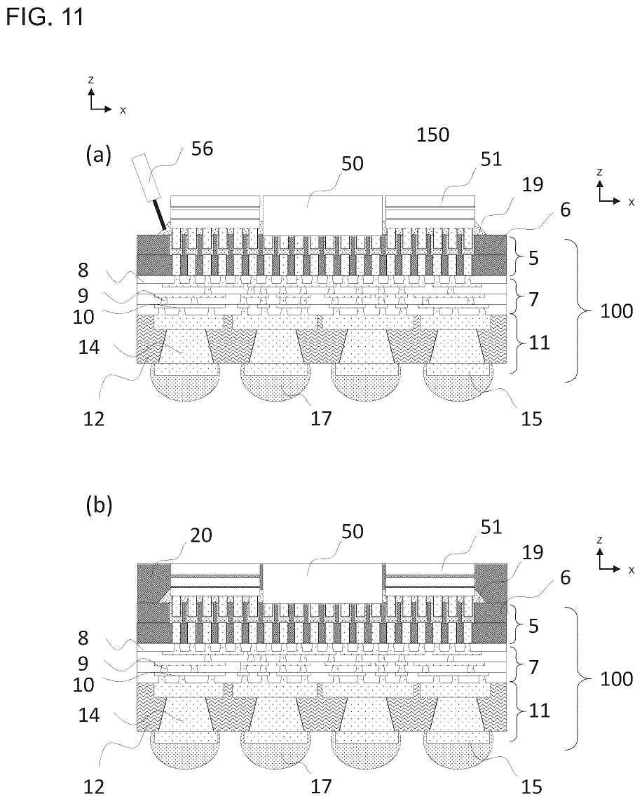

FIG. 11(a) is a drawing showing a capillary underfill step in which the underfill 19 is formed by using an underfill supply device 56 on the semiconductor package 150 according to the present embodiment having the plurality of semiconductor devices installed. After the inspection and the correction, it is possible, by using the underfill 19, to fix the semiconductor devices on the interposer according to the present embodiment.

FIG. 11(b) is a schematic cross-sectional view showing a result of further forming the mold resin 20 on the semiconductor devices. The present fixation step using the mold resin is not necessarily a requisite step. Further, for the fixation using the mold, it is possible to adopt a publicly-known method as appropriate. In addition, it is also acceptable to cause upper ends of the semiconductor devices to expose, by polishing the upper surface of the mold resin 20.

Through the steps shown in FIG. 10(a) to 11(a) or 11(b) described above, It is possible to produce the semiconductor package 150 having the semiconductor devices installed. According to the present embodiment, because the interposer is provided independently, the following advantages are achieved.
1) It is possible to use, in the assembly step, the interposer that has been inspected and guaranteed as (Y_{INTERPOSER})=100%. Further, by having repairs and corrections, it is possible to make the yield closer to (Y_{ASSEMBLY})=100%. Thus, it is possible to improve the SiP construction total yield.
2) Because the FC-BGA and the interposer 100 are independent, it is possible to install the semiconductor devices on the interposer so as to subsequently assemble the resulting semiconductor package onto the FC-BGA or a mother board. Alternatively, it is also possible to assemble the interposer on the FC-BGA or a motherboard and to subsequently install the semiconductor devices thereon. It is therefore possible to enhance the degree of freedom in the manufacturing steps.
3) As for the CTEs of the various members also, the interposer is able to have an intermediate value between the values of the semiconductor devices and the FC-BGA substrate. Thus, by constructing the semiconductor devices and the interposer together at first and subsequently assembling the constructed combination onto the BGA, it is possible to intermediate the matching of the CTEs between the semiconductor devices and the FC-BGA and to thus make contribution to enhancing reliability of the connections.
4) It is also possible to select, as appropriate, a configuration in which the interposer is directly connected to a mother board without the intermediation of the FC-BGA.

The embodiment of the present invention has thus been explained; however, the present invention is not limited to the embodiment described above. It is possible to apply various changes without departing from the gist of the present invention.

For example, in the above embodiment, the example was explained in which the first outer layer structure is formed prior to the second outer layer structure. However, the sequential order for forming these structures is not at all limited. It is also acceptable to carry out production on the support substrate starting with the second outer layer structure (i.e., the side connected to a BGA or a mother board) and to subsequently form the first outer layer structure.

Further, for the sake of convenience, only one interposer is shown in FIGS. 5(a) to 9(r) depicting outlines of the method for manufacturing the interposer according to the present embodiment. However, needless to say, the manufacturing methods of the present disclosure may be applied to manufacturing steps performed while a single interposer is formed on a plurality of square panels or circular wafers.

Furthermore, there is no limitation to the shape of the manufacturing panel and the thickness and the size of the support substrate described in the present disclosure. It is possible to adopt any shape and size as appropriate.

The following will describe certain aspects that can be part of the present invention. However, possible embodiments are not limited to these examples.

### (Aspect 1)

An interposer including:
an inner layer structure including at least one inner layer wiring layer;
a first outer layer structure provided on a first surface of the inner layer structure; and
a second outer layer structure provided on a second surface of the inner layer structure, wherein
the inner layer wiring layer includes a first insulating resin layer, a wiring provided on a surface of the first insulating resin layer, and a via being connected to the wiring and penetrating the first insulating resin layer,
the first outer layer structure and the second outer layer structure each include a second insulating resin layer and an external connection via penetrating the second insulating resin layer, and
the second insulating resin layer has an external connection opening part so as to make it possible for an external connection electrode of a semiconductor device to fit into a surface of one of the first outer layer structure and the second outer layer structure.

### (Aspect 2)

The interposer according to aspect 1, wherein
the external connection opening part has a circular shape.

### (Aspect 3)

The interposer according to aspect 1 or 2, wherein
the external connection opening part has a tapered shape.

### (Aspect 4)

The interposer according to any one of aspects 1 to 3, wherein
the external connection opening part is provided with a conductive adhesive agent.

### (Aspect 5)

The interposer according to aspect 4, wherein
the conductive adhesive agent is solder.

### (Aspect 6)

The interposer according to any one of aspects 1 to 5, wherein
an elastic modulus of the second insulating resin layer in at least one of the first outer layer structure and the second outer layer structure is higher than an elastic modulus of the first insulating resin layer.

### (Aspect 7)

The interposer according to any one of aspects 1 to 6, wherein
the second insulating resin layer includes at least mold resin or resin enclosing glass fiber.

### (Aspect 8)

A semiconductor package in which the semiconductor device is installed on
the interposer according to any one of aspects 1 to 7.

### (Aspect 9)

The semiconductor package according to aspect 8, wherein
a joint part between the external connection via and the external connection electrode is positioned within the second insulating resin layer with respect to a thickness direction of the semiconductor device.

### (Aspect 10)

A method for manufacturing the interposer according to any one of aspects 1 to 7, comprising:
a first step of forming the first outer layer structure on a support substrate;
a second step of forming the inner layer structure on the first outer layer structure;
a third step of forming the second outer layer structure on the inner layer structure;
a fourth step of peeling the first outer layer structure and the support substrate from each other;
a fifth step of forming the external connection opening part above the external connection via in the first outer layer structure; and
a sixth step of forming connection terminals on outermost layers of the first outer layer structure and the second outer layer structure.

### (Aspect 11)

A method for manufacturing the interposer according to any one of aspects 1 to 7, comprising:
a first step of forming the second outer layer structure on a support substrate;
a second step of forming the inner layer structure on the second outer layer structure;
a third step of forming the first outer layer structure on the inner layer structure;
a fourth step of forming the external connection opening part above the external connection via in the first outer layer structure;
a fifth step of peeling the second outer layer structure and the support substrate from each other; and
a sixth step of forming connection terminals on outermost layers of the first outer layer structure and the second outer layer structure.

### (Aspect 12)

A method for manufacturing the semiconductor package according to aspect 8 or 9, comprising:
a first step of forming the first outer layer structure on a support substrate;
a second step of forming the inner layer structure on the first outer layer structure;
a third step of forming the second outer layer structure on the inner layer structure;
a fourth step of peeling the first outer layer structure and the support substrate from each other;
a fifth step of forming the external connection opening part above the external connection via in the first outer layer structure;
a sixth step of forming connection terminals on outermost layers of the first outer layer structure and the second outer layer structure; and
a seventh step of installing the semiconductor device.

### (Aspect 13)

A method for manufacturing the semiconductor package according to aspect 8 or 9, comprising:
a first step of forming the second outer layer structure on a support substrate;
a second step of forming the inner layer structure on the second outer layer structure;
a third step of forming the first outer layer structure on the inner layer structure;
a fourth step of forming the external connection opening part above the external connection via in the first outer layer structure;
a fifth step of peeling the second outer layer structure and the support substrate from each other;
a sixth step of forming connection terminals on outermost layers of the first outer layer structure and the second outer layer structure; and
a seventh step of installing the semiconductor device.

### REFERENCE SIGNS LIST

1: support substrate, 2: metal layer, 3: resist pattern, 4: external connection via, 5: first outer layer structure, 6: second insulating resin layer, 7: inner layer structure, 8: first insulating resin layer, 9: via, 10: wiring, 11: second outer layer structure, 12: second insulating resin layer, 13: thin copper foil, 14: external connection via, 15: pad, 16: first connection terminal, 17: second connection terminal, 18: testing probe, 19: underfill, 20: mold resin, 21: external connection opening part, 50, 51, 52, 53: semiconductor device, 54: external connection electrode of semiconductor device, 55: connection terminal of semiconductor device, 56: underfill supply device, 100: interposer, 150: semiconductor package.

1. An interposer including:
an inner layer structure including at least one inner layer wiring layer;
a first outer layer structure provided on a first surface of the inner layer structure; and
a second outer layer structure provided on a second surface of the inner layer structure, wherein
the inner layer wiring layer includes a first insulating resin layer, a wiring provided on a surface of the first insulating resin layer, and a via being connected to the wiring and penetrating the first insulating resin layer,
the first outer layer structure and the second outer layer structure each include a second insulating resin layer and an external connection via penetrating the second insulating resin layer, and
the second insulating resin layer has an external connection opening part so as to make it possible for an external connection electrode of a semiconductor device to fit into a surface of one of the first outer layer structure and the second outer layer structure.

2. The interposer according to claim 1, wherein
the external connection opening part has a circular shape.

3. The interposer according to claim 1, wherein
the external connection opening part has a tapered shape.

4. The interposer according to claim 1, wherein
the external connection opening part is provided with a conductive adhesive agent.

5. The interposer according to claim 4, wherein
the conductive adhesive agent is solder.

6. The interposer according to claim 1, wherein
an elastic modulus of the second insulating resin layer in at least one of the first outer layer structure and the second outer layer structure is higher than an elastic modulus of the first insulating resin layer.

7. The interposer according to claim 1, wherein
the second insulating resin layer includes at least mold resin or resin enclosing glass fiber.

8. A semiconductor package in which the semiconductor device is installed on the interposer according to claim 1.

9. The semiconductor package according to claim 8, wherein
a joint part between the external connection via and the external connection electrode is positioned within the second insulating resin layer with respect to a thickness direction of the semiconductor device.

10. A method for manufacturing the interposer according to claim 1, comprising:
a first step of forming the first outer layer structure on a support substrate;
a second step of forming the inner layer structure on the first outer layer structure;
a third step of forming the second outer layer structure on the inner layer structure;
a fourth step of peeling the first outer layer structure and the support substrate from each other;
a fifth step of forming the external connection opening part above the external connection via in the first outer layer structure; and
a sixth step of forming connection terminals on outermost layers of the first outer layer structure and the second outer layer structure.

11. A method for manufacturing the interposer according to claim 1, comprising:
a first step of forming the second outer layer structure on a support substrate;
a second step of forming the inner layer structure on the second outer layer structure;
a third step of forming the first outer layer structure on the inner layer structure;
a fourth step of forming the external connection opening part above the external connection via in the first outer layer structure;
a fifth step of peeling the second outer layer structure and the support substrate from each other; and
a sixth step of forming connection terminals on outermost layers of the first outer layer structure and the second outer layer structure.

12. A method for manufacturing the semiconductor package according to claim 8, comprising:
a first step of forming the first outer layer structure on a support substrate;
a second step of forming the inner layer structure on the first outer layer structure;
a third step of forming the second outer layer structure on the inner layer structure;
a fourth step of peeling the first outer layer structure and the support substrate from each other;
a fifth step of forming the external connection opening part above the external connection via in the first outer layer structure;
a sixth step of forming connection terminals on outermost layers of the first outer layer structure and the second outer layer structure; and
a seventh step of installing the semiconductor device.

13. A method for manufacturing the semiconductor package according to claim 8, comprising:
a first step of forming the second outer layer structure on a support substrate;
a second step of forming the inner layer structure on the second outer layer structure;
a third step of forming the first outer layer structure on the inner layer structure;
a fourth step of forming the external connection opening part above the external connection via in the first outer layer structure;
a fifth step of peeling the second outer layer structure and the support substrate from each other;
a sixth step of forming connection terminals on outermost layers of the first outer layer structure and the second outer layer structure; and
a seventh step of installing the semiconductor device.

14. A semiconductor package in which the semiconductor device is installed on the interposer according to claim 6.

15. The semiconductor package according to claim 14, wherein
a joint part between the external connection via and the external connection electrode is positioned within the second insulating resin layer with respect to a thickness direction of the semiconductor device.

16. A method for manufacturing the interposer according to claims 6, comprising:
a first step of forming the first outer layer structure on a support substrate;
a second step of forming the inner layer structure on the first outer layer structure;
a third step of forming the second outer layer structure on the inner layer structure;
a fourth step of peeling the first outer layer structure and the support substrate from each other;
a fifth step of forming the external connection opening part above the external connection via in the first outer layer structure; and
a sixth step of forming connection terminals on outermost layers of the first outer layer structure and the second outer layer structure.

17. A method for manufacturing the interposer according to claims 6, comprising:
a first step of forming the second outer layer structure on a support substrate;
a second step of forming the inner layer structure on the second outer layer structure;
a third step of forming the first outer layer structure on the inner layer structure;
a fourth step of forming the external connection opening part above the external connection via in the first outer layer structure;
a fifth step of peeling the second outer layer structure and the support substrate from each other; and
a sixth step of forming connection terminals on outermost layers of the first outer layer structure and the second outer layer structure.

18. A method for manufacturing the semiconductor package according to claim 14, comprising:
a first step of forming the first outer layer structure on a support substrate;
a second step of forming the inner layer structure on the first outer layer structure;
a third step of forming the second outer layer structure on the inner layer structure;
a fourth step of peeling the first outer layer structure and the support substrate from each other;
a fifth step of forming the external connection opening part above the external connection via in the first outer layer structure;
a sixth step of forming connection terminals on outermost layers of the first outer layer structure and the second outer layer structure; and
a seventh step of installing the semiconductor device.

19. A method for manufacturing the semiconductor package according to claim 14, comprising:
a first step of forming the second outer layer structure on a support substrate;
a second step of forming the inner layer structure on the second outer layer structure;
a third step of forming the first outer layer structure on the inner layer structure;
a fourth step of forming the external connection opening part above the external connection via in the first outer layer structure;
a fifth step of peeling the second outer layer structure and the support substrate from each other;
a sixth step of forming connection terminals on outermost layers of the first outer layer structure and the second outer layer structure; and
a seventh step of installing the semiconductor device.
